(19) United States
(12) Patent Application Publication
(10) Pub. No.: US 2008/0122126 A1
(43) Pub. Date: May 29, 2008

(54) Bose-Einstein Condensate Bottling Plant

(76) Inventor: Itai Aaronson, Ashland, OR (US)

Correspondence Address: Itai Aaronson, 593 Oak Knoll Drive, Ashland, OR, 97520, US

(21) Appl. No.: 11/563,211

(22) Filed: Nov. 26, 2006

(51) Int. Cl. H01L 23/00

(52) U.S. Cl. 257/798

(57) ABSTRACT

This is a method for creating Bose-Einstein condensates using low-cost technology at room temperature. The method includes a convenient way for separating the condensate into parts that remain entangled and storing the parts in reliable and stable containers that are suitable for easy transportation. The containers have a convenient method to monitor changes in the state of the condensate.

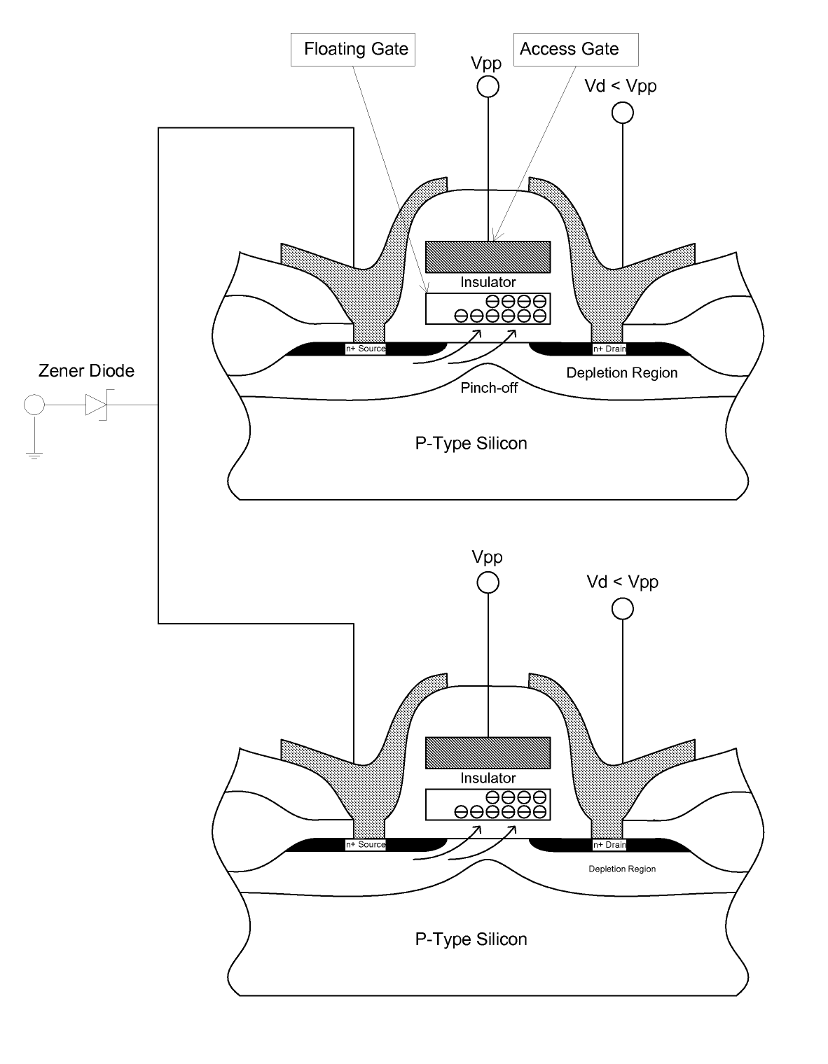

1. Vₚₚ and V_{d} are adjusted such that the voltage across the Zener diode is very close to the breakdown voltage for the device and V_{d} is less than Vₚₚ.

2. A cloud of electrons, the majority of which are at the same quantum energy state, crosses the Zener diode junction. This cloud of electrons is an entangled Bose-Einstein condensate.

3. The condensate proceeds and splits into nearly equal parts. One part enters the source gate of the upper device in the drawing. The 2^{nd} part enters the source gate of the lower device in the drawing.

4. Each condensate proceeds to be trapped in the floating gate of the device it had entered.

5. The circuit is powered off.

6. Each device can be transported to any distance while maintaining the entanglement of the two condensates.

7. Current semi-conductor technology is available to construct such devices that can maintain the condensates for many years and at a wide range of temperatures.

8. The drawing illustrates an NPN-type silicon device. Both NPN and PNP devices can be fabricated of a wide variety of semi-conductor materials.

9. The device can have additional floating gates that would be staggered at different heights above the pinch-off region. Application of different voltages at Vₚₚ will result in the condensate acquiring a different quantum energy state and migrating to a different floating gate.

10. Once the condensate in one device migrates, the condensate in the other device migrates as well.

11. The exact floating gate residence of the condensate can be detected by measuring the conductivity between the source and the drain of the device.

12. This technique can be used to construct:
a. Secure communication devices that are not bound by the speed of light.
b. Quantum computing circuits with large number of Qubits.
c. Self-generating vacuum energy power plants.

The enclosed drawing illustrates a circuit containing two floating gate transistors and a Zener diode. The Zener diode is used to create a Bose-Einstein condensate. The circuit separates the condensate into two entangled parts. One of the parts is stored in one of the floating gate transistors and the other part is stored in the other floating gate transistor.
1. V_{PP} and V_{d} are adjusted such that the voltage across the Zener diode is very close to the breakdown voltage for the device and V_{d} is less than Vₚₚ.
2. A cloud of electrons, the majority of which are at the same quantum energy state, crosses the Zener diode junction. This cloud of electrons is an entangled Bose-Einstein condensate.
3. The condensate proceeds and splits into nearly equal parts. One part enters the source gate of the upper device in the drawing. The 2^{nd} part enters the source gate of the lower device in the drawing.
4. Each condensate proceeds to be trapped in the floating gate of the device it had entered.
5. The circuit is powered off.
6. Each device can be transported to any distance while maintaining the entanglement of the two condensates.
7. Current semi-conductor technology is available to construct such devices that can maintain the condensates for many years and at a wide range of temperatures.
8. The drawing illustrates an NPN-type silicon device. Both NPN and PNP devices can be fabricated of a wide variety of semi-conductor materials.
9. The device can have additional floating gates that would be staggered at different heights above the pinch-off region. Application of different voltages at Vₚₚ will result in the condensate acquiring a different quantum energy state and migrating to a different floating gate.
10. Once the condensate in one device migrates, the condensate in the other device migrates as well.
11. The exact floating gate residence of the condensate can be detected by measuring the conductivity between the source and the drain of the device.
12. This technique can be used to construct:
   a. Secure communication devices that are not bound by the speed of light.
   b. Quantum computing circuits with large number of Qubits.
   c. Self-generating vacuum energy power plants.

1. Current art for creating and containing Bose-Einstein condensates is very expensive, requires very low temperatures, is very bulky and is impractical for reliable transportation of condensates. This invention utilizes very low cost components, is stable within a wide range of temperatures, is easy to transport across great distances and is in the sub-micron size range, thus this invention is an improvement over existing art.

2. Current art does not allow for practical division of condensates. This invention enables divisions of condensates in a practical manner and thus offers an improvement over existing art.

3. Current art does not allow for the creation of large scale quantum computing circuits. This invention enables the creation of large scale quantum computing circuits and thus offers an improvement over existing art

4. Current art does not allow for practical quantum entanglement based secure communication systems. This invention enables the creation of practical quantum entanglement based secure communication systems and thus offers an improvement over existing art.

5. Current art does not allow for practical Bose-Einstein-Condensate-based Self-generating vacuum energy power plants. This invention enables the creation of practical Bose-Einstein-Condensate-based Self-generating vacuum energy power plants and thus offers an improvement over existing art.
